(19) United States
(12) Patent Application Publication
(10) Pub. No.: US 2016/0165756 A1
(43) Pub. Date: Jun. 9, 2016

(54) HEAT DISSIPATION DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: BO YANG, Wuhan (CN); XU LI, Wuhan (CN)

(21) Appl. No.: 14/684,060

(22) Filed: Apr. 10, 2015

(30) Foreign Application Priority Data
Dec. 8, 2014 (CN) 201410739468.2

(51) Int. Cl. H05K 7/20

(52) U.S. Cl. CPC H05K 7/20336

(57) ABSTRACT

A heat dissipation device includes a mounting plate, a base, a first fin assembly, a heat pipe, and a second fin assembly separated from the first fin assembly. The first fin assembly is disposed on a top surface of the base. A bottom surface of the base can contact an electronic component. The fan module is located between the first fin assembly and the second fin assembly. The heat pipe is connected to the first fin assembly and the second fin assembly. The first fin assembly and the second fin assembly are mounted to the mounting plate. The heat pipe is located in a first plane, and the first plane coincides with an axis of the heat pipe. The mounting plate is located in a second plane parallel with the mounting plate, and the first plane intersects with the second plane.

### CROSS-REFERENCE TO RELATED APPLICATIONS

This application claims priority to Chinese Patent Application No. 201410739468.2 filed on Dec. 8, 2014, the contents of which are hereby incorporated by reference.

### FIELD

The subject matter herein generally relates to heat dissipation devices, and more particularly to a heat dissipation device which can dissipate heat generated from an electronic component.

### BACKGROUND

Some components in an electronic system generate a lot of heat during operation. Excess heat may cause deterioration in the operational stability of the components and may damage the components. A heat dissipation device is generally assembled in a chassis of the electronic system for dissipating heat generated from the components.

### BRIEF DESCRIPTION OF THE DRAWINGS

Implementations of the present technology will now be described, by way of example only, with reference to the attached figures.

FIG. 1 is an exploded, isometric view of an electronic system in accordance with an embodiment.

FIG. 2 is an exploded, isometric view of a heat dissipation of FIG. 1.

FIG. 3 is an assembled, isometric view of the heat dissipation of FIG. 2.

FIG. 4 is a side view of the heat dissipation of FIG. 3.

FIG. 5 is an assembled, isometric view of the electronic system of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

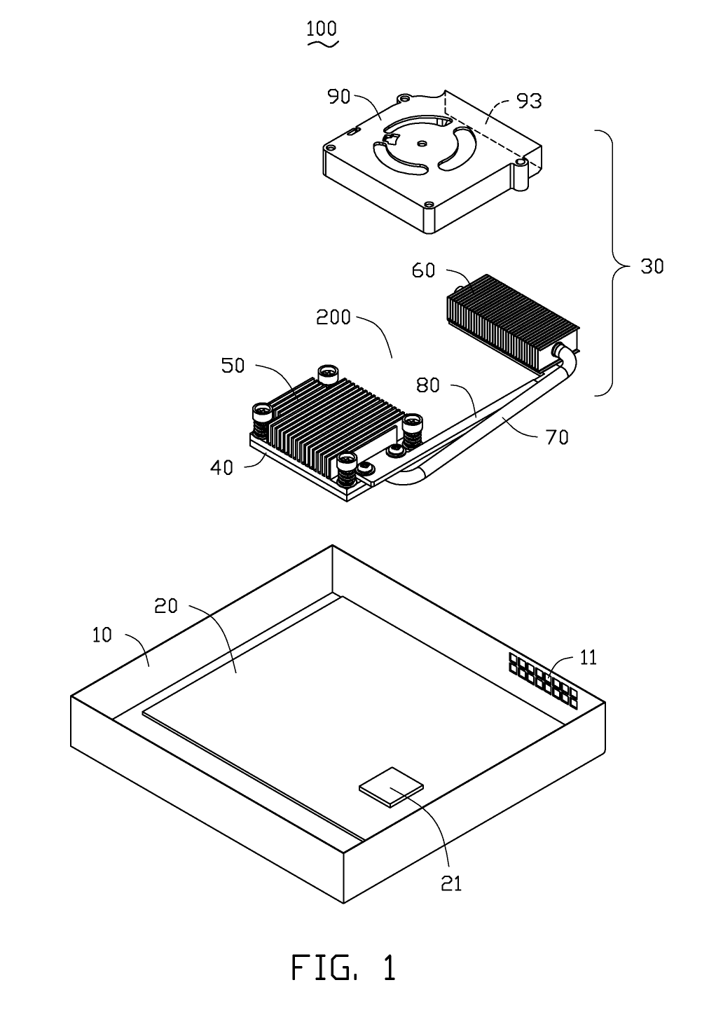

FIG. 1 illustrates an embodiment of an electronic system 100 includes a chassis 10, a heat dissipation device 30, and a circuit board 20 mounted in the chassis 10. The chassis 10 defines a plurality of vents 11. The circuit board 20 includes an electronic component 21. The electronic component 21, can be, for example, a central processing unit that generates heat during operation.

The heat dissipation device 30 can include a base 40, a first fin assembly 50, a second fin assembly 60, a heat pipe 70, a mounting plate 80, and a unidirectional fan module 90.

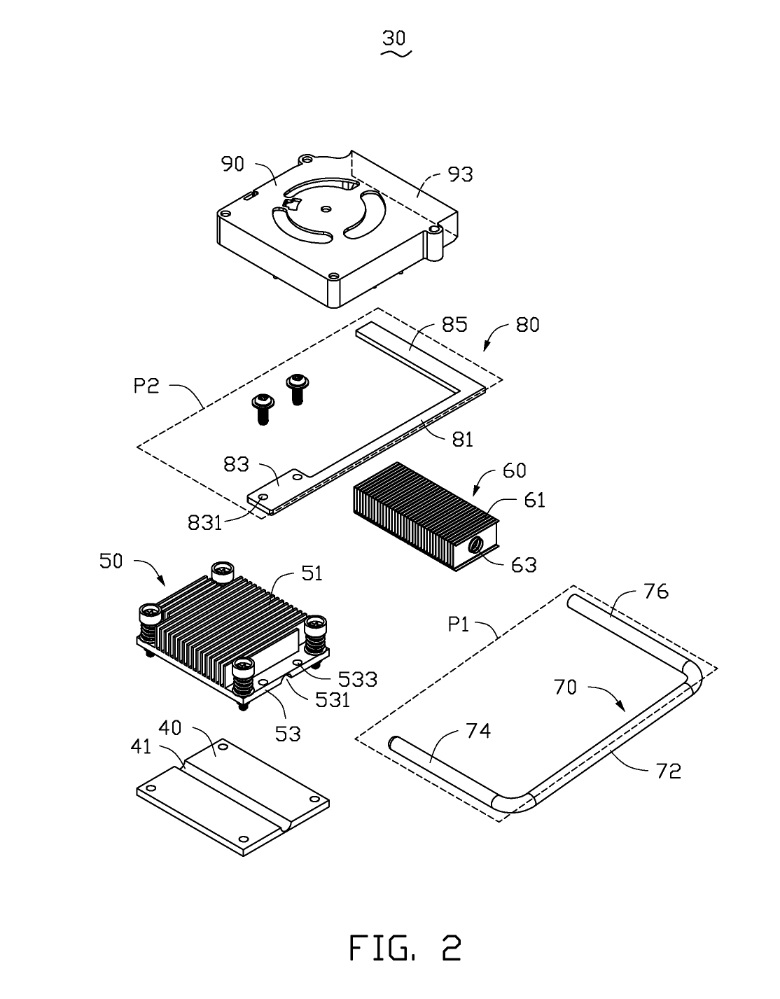

FIG. 2 illustrates the base 40 defining a receiving groove 41. The receiving groove 41 extends lengthwise along the base 40 and across a top surface of the base 40.

The first fin assembly 50 can include a bottom plate 53 and a plurality of parallel first fins 51 extending from a top surface of the bottom plate 53. A bottom surface of the bottom plate 53 defines a cutout groove 531 which matches an internal shape of the receiving groove 41. An extending direction of the cutout groove 531 is parallel to that of the receiving groove 81 and substantially perpendicular to each of the plurality of first fins 51. The bottom plate 53 further defines two through holes 533 located at two opposite sides of the cutout groove 531.

The second fin assembly 60 can include a plurality of parallel second fins 61 and defines a securing hole 63 extending through each of the plurality of second fins 61. An extending direction of the securing hole 63 is substantially perpendicular to each of the plurality of second fins 61.

The heat pipe 70 is substantially U-shaped and can include a connecting portion 72, a first contacting portion 74, and a second contacting portion 76. The first contacting portion 74 and the second contacting portion 76 are substantially perpendicular to the connecting portion 72 and extend from two opposite ends of the connecting portion 72. The first contacting portion 74 and the second contacting portion 76 are parallel to each other. The connecting portion 72, the first contacting portion 74, and the second contacting portion 76 are substantially located in a same first plane P1. The first plane P1 coincides with an axis of the heat pipe 70.

The mounting plate 80 is substantially L-shaped and configured to mount the first fin assembly 50 and the second fin assembly 60. The mounting plate 80 can include a connecting piece 81, a mounting piece 83, and a retaining piece 85. The mounting piece 83 and the retaining piece 85 are substantially perpendicular to the connecting piece 81 and extend from two opposite ends of the connecting piece 81. The mounting piece 83 and the retaining piece 85 are substantially parallel to each other. A length of the retaining piece 85 is greater than that of the mounting piece 83. The connecting piece 81, the mounting piece 83, and the retaining piece 85 are substantially located in a same second plane P2. The second plane P2 is parallel to the mounting plate 80. The mounting piece 83 defines two mounting holes 831 corresponding to the two through holes 533 of the bottom plate 53.

The unidirectional fan module 90 can include an air outlet 93. The unidirectional fan module 90 can generate airflow and output the airflow through the air outlet 93. A height of the air outlet 93 is substantially the same as that of the second fin assembly 60.

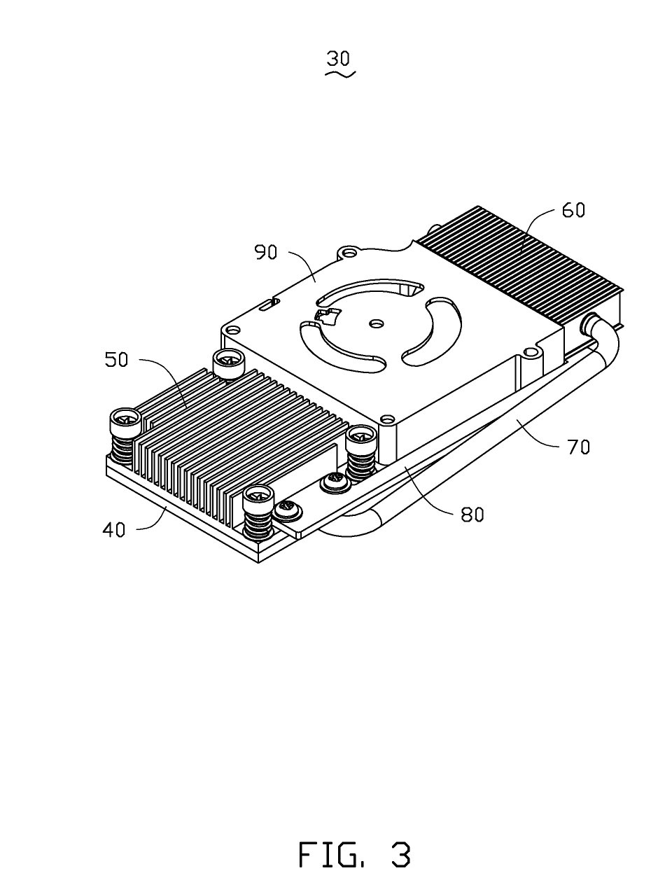

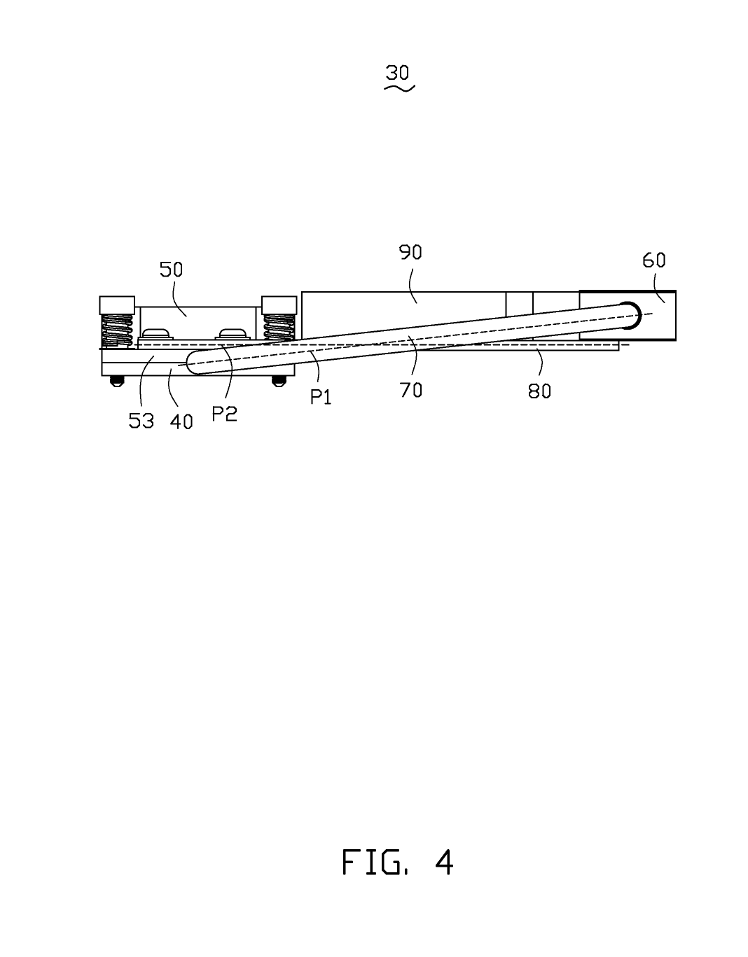

FIGS. 3 and 4 illustrate the heat dissipation device 30 in assembly. The first contacting portion 74 (shown in FIG. 2) is received in the receiving groove 41 of the base 40. The first fin assembly 50 is positioned above the base 40. The cutout groove 531 is aligned with the receiving groove 41. The first fin assembly 50 is moved towards the base 40 until the bottom surface of the first fin assembly 50 contacts the top surface of the base 40. The first contacting portion 74 is received in a receiving hole defined by the receiving groove 531 and the cutout groove 531 together. Thus, the first contacting portion 74 is in contact with both the base 40 and the first fin assembly 50.

The second contacting portion 76 of the heat pipe 70 is inserted into the securing hole 63 of the second fin assembly 60. A diameter of the cross section of the second contacting portion 76 is substantially the same as that of the securing hole 63 so that the second contacting portion 76 is in contact with the inner surface(s) of the securing hole 63.

The mounting plate 80 is moved towards the first fin assembly 50 and the second fin assembly 60, until the mounting piece 83 contacts the top surface of the bottom plate 53 and the retaining piece 85 contacts a bottom surface of the second fin assembly 60. Two fasteners (not shown) are inserted into the two mounting holes 531 and engaged in the through holes 533. The mounting piece 83 is fixed to the first fin assembly 50, and the second fin assembly 60 is supported by the retaining piece 85. The second plane P2 of the mounting plate 80 is horizontal, and the first plane P1 of the heat pipe 70 is inclined upward from the top surface of the base 40. The first plane P1 intersects with the second plane P2, and an acute angle is defined between the first plane P1 and the second plane P2. In at least one embodiment, the second fin assembly 60 is mounted on the retaining piece 85.

The first fin assembly 50 and the second fin assembly 60 are separate from each other, and a receiving space 200 (shown in FIG. 1) is located between the first fin assembly 50 and the second fin assembly 60. The second fin assembly 60 is located in a horizontal position higher than the first pin assembly 50. The plurality of second fins 61 is substantially parallel to the plurality of first fins 51.

The unidirectional fan module 90 is coupled to the second fin assembly 60 and received in the receiving space 200. The air outlet 93 faces the second fin assembly 60 and is connected to a side of the second fin assembly 60. The unidirectional fan module 90 is spaced from the first fin assembly 50. The heat dissipation device 30 is assembled. Thus, the airflow from the unidirectional fan module 90 blows towards and through the second fin assembly 60 through the air outlet 93 and removes heat from the second fin assembly 60.

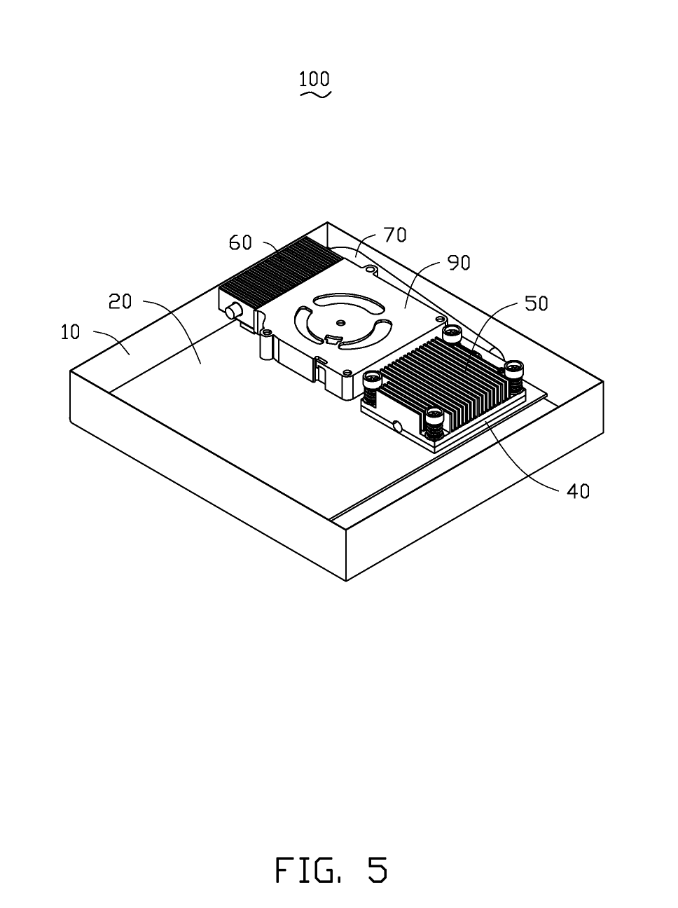

FIG. 5 illustrates the electronic system 100 in assembly. The heat dissipation device 30 is mounted on the circuit board 20 in the chassis 10. A bottom surface of the base 40 contacts the component 21. In at least one embodiment, to dissipate heat generated from the component 21, a side of the second fin assembly 60 opposite to the unidirectional fan module 90 passes through the second fin assembly and the heated airflow exits the chassis 10 via the plurality of vents 11.

The embodiments shown and described above are only examples. Many details are often found in the art such as the other features of a heat dissipation device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A heat dissipation device comprising:
a mounting plate;
a base comprising a top surface and a bottom surface configured to contact an electronic component;
a first fin assembly disposed on the top surface of the base;
a second fin assembly separated from the first fin assembly;
a fan module located between the first fin assembly and a second fin assembly; and
a heat pipe connected to the first fin assembly and the second fin assembly;
wherein the first fin assembly and the second fin assembly are mounted to the mounting plate, the heat pipe is located in a first plane, and the first plane coincides with an axis of the heat pipe; the mounting plate is located in a second plane parallel to the mounting plate, and the first plane intersects with the second plane.

2. The heat dissipation device of claim 1, wherein the mounting plate comprises a connecting piece, a mounting piece, and a retaining piece; the mounting piece and the retaining piece extend from two opposite ends of the connecting piece; the first fin assembly is mounted to the mounting piece, and the second fin assembly is mounted to the retaining piece.

3. The heat dissipation device of claim 2, wherein the mounting piece and the retaining piece are substantially perpendicular to the connecting piece and parallel to each other.

4. The heat dissipation device of claim 1, wherein the heat pipe comprises a connecting portion, a first contacting portion, and a second contacting portion; the first contacting portion and the second contacting portion extend from two opposite ends of the connecting portion; the first contacting portion is located between the first fin assembly and the base, and the second contacting portion is mounted in the second fin assembly.

5. The heat dissipation device of claim 4, wherein the first contacting portion and the second contacting portion are substantially perpendicular to the connecting portion and parallel to each other.

6. The heat dissipation device of claim 1, wherein an acute angle is defined between the first plane and the second plane.

7. The heat dissipation device of claim 1, wherein the first plane is inclined upward from the top surface of the base.

8. The heat dissipation device of claim 1, wherein the second plane is horizontal.

9. The heat dissipation device of claim 1, wherein the second fin assembly is located in a horizontal position higher than the first fin assembly.

10. The heat dissipation device of claim 1, wherein the fan module defines an air outlet facing to the second fin assembly, and the fan module is spaced from the first fin assembly.

11. A heat dissipation device comprising:
a base comprising a top surface and a bottom surface configured to contact an electronic component;
a first fin assembly disposed on the top surface of the base and comprising a bottom plate;
a mounting plate mounted on a top surface of the bottom plate;
a second fin assembly separated from the first fin assembly and supported by the mounting plate; and
a heat pipe comprising a first contacting portion in contact with the base and a second contacting portion in contact with the second fin assembly.

12. The heat dissipation device of claim 11, wherein an acute angle is defined by the mounting plate and the heat pipe.

13. The heat dissipation device of claim 11, wherein the heat pipe further comprises a connecting portion interconnecting the first contacting portion and the second contacting portion; the first contacting portion, the second portion, and the connecting portion are located in a plane inclined upward from the top surface of the base.

14. The heat dissipation device of claim 13, wherein the heat pipe is U-shaped.

15. The heat dissipation device of claim 11, wherein a receiving groove is defined in the top surface of the base, and the first contacting portion is received in the receiving groove.

16. The heat dissipation device of claim 15, wherein a cutout groove is defined in the bottom plate of the first fin assembly, the receiving groove together with the cutout groove define a receiving hole, and the first contacting portion is received in the receiving hole.

17. The heat dissipation device of claim 11, wherein the second fin assembly is located in a horizontal position higher than the first fin assembly.

18. The heat dissipation device of claim 11, further comprising a fan module located between the first fin assembly and the second fin assembly, wherein the fan module comprises an air outlet communicating a side of the second fin assembly.
